(19) United States
(12) Patent Application Publication
(10) Pub. No.: US 2026/0040999 A1
(43) Pub. Date: Feb. 5, 2026

(54) ELECTRICAL CONNECTIONS IN SEMICONDUCTOR DEVICE

(71) Applicant: SK hynix Inc., Icheon-si Gyeonggi-do (KR)

(72) Inventor: Choung Ki SONG, Icheon-si Gyeonggi-do (KR)

(73) Assignee: SK hynix Inc., Icheon-si Gyeonggi-do (KR)

(21) Appl. No.: 18/980,735

(22) Filed: Dec. 13, 2024

(30) Foreign Application Priority Data
Aug. 1, 2024 (KR) 10-2024-0102588

(51) Int. Cl. H01L 25/18; H01L 23/00; H01L 23/498; H01L 23/538; H01L 25/065; H10D 88/00

(52) U.S. Cl. CPC H01L 25/18; H01L 23/49816; H01L 23/49827; H01L 23/5384; H01L 23/5386; H01L 24/16; H01L 25/0657; H10D 88/00; H01L 2224/16146; H01L 2224/16238; H01L 2924/1436

(57) ABSTRACT

A semiconductor device includes a base chip including a first base pad, a second base pad, and a third base pad and a core chip including a first path including first plurality of core pads, a second path including a second plurality of core pads, and a third path including a third plurality of core pads. The first base pad is electrically connected to one of the first plurality of core pads. The second base pad is electrically connected to one of the second plurality of core pads. The third base pad is electrically connected to one of the third plurality of core pads. The base chip and the core chip are stacked.

### CROSS-REFERENCE TO RELATED APPLICATION

This application claims priority under 35 U.S.C. § 119(a) to Korean Patent Application No. 10-2024-0102588, filed in the Korean Intellectual Property Office on Aug. 1, 2024, the entire contents of which application is incorporated herein by reference.

### BACKGROUND

### 1. Technical Field

The present disclosure relates to a semiconductor device, including but not limited to electrical connections in a semiconductor device including a plurality of pads and core chips.

### 2. Related Art

As technology for manufacturing semiconductor devices is developed, packaging technology for core chips within the semiconductor device is increasingly achieving higher integration and higher performance. As packaging technologies for semiconductor devices are developed, technology relating to three-dimensional structures in which core chips are vertically stacked gradually varies from technology relating to two-dimensional structures in which a plurality of core chips are disposed in a flat layout on a printed circuit board (PCB). Semiconductor device having three-dimensional structures are implemented by stacking the plurality of core chips using at least one through silicon via (TSV) referred to as a “through electrode” or by stacking the plurality of core chips and utilizing wire bonding, such as utilized in high bandwidth memory (HBM).

### SUMMARY

In an embodiment, a semiconductor device may include a base chip including a first base pad, a second base pad, and a third base pad and a core chip including a first path including a first plurality of core pads, a second path including a second plurality of core pads, and a third path including a third plurality of core pads. The first base pad is electrically connected to one of the first plurality of core pads. The second base pad is electrically connected to one of the second plurality of core pads. The third base pad is electrically connected to one of the third plurality of core pads. The base chip and the core chip are stacked.

In an embodiment, a semiconductor device may include a base chip including a base pad disposed between an interface circuit and a memory controller and configured to receive a power supply voltage, a first core chip including a first path including a first plurality of core pads disposed between a first channel region and a second channel region, and a second core chip including a second path including a second plurality of core pads disposed between a third channel region and a fourth channel region. The base pad is electrically connected to one of the first plurality of core pads and electrically connected to one of the second plurality of core pads. The base chip, the first core chip, and the second core chip are stacked.

In an embodiment, a semiconductor device may include a base chip including a base pad disposed in a first direction with an interface circuit and a memory controller, a first core chip including a first path including a first plurality of core pads disposed in the first direction with a first channel region and a second channel region, and a second core chip including a second path including a second plurality of core pads disposed in the first direction with a third channel region and a fourth channel region. The base pad is electrically connected to one of the first plurality of core pads and electrically connected to one of the second plurality of core pads. The base chip, the first core chip, and the second core chip are stacked.

In an embodiment, a semiconductor device may include a base chip including a base pad disposed in a region between a surface of the base chip and an interface circuit and a memory controller of the base chip, a first core chip including a first path including a first plurality of core pads disposed in a region between a surface of the first core chip and a first channel region and a second channel region of the first core chip, and a second core chip including a second path including a second plurality of core pads disposed in a region between a surface of the of the second core chip and a third channel region and a fourth channel region. The base pad is electrically connected to one of the first plurality of core pads and electrically connected to one of the second plurality of core pads. The base chip, the first core chip, and the second core chip are stacked.

In an embodiment, a semiconductor device may include a base chip comprising a base pad at a first location of a plurality of locations; and a core chip comprising a first path comprising a plurality of core pads. The first base pad is electrically connected to one of the plurality of core pads at a location corresponding to the first location, and the base chip and the core chip are stacked.

### BRIEF DESCRIPTION OF THE DRAWINGS

FIG. 1 is a block diagram illustrating a semiconductor device according to an embodiment of the present disclosure.

FIG. 2 is a diagram illustrating a perspective view of connections between pads of a base chip and pads of core chips of a semiconductor device according to an embodiment.

FIG. 3 is a diagram illustrating a perspective view of connections between pads of a base chip and pads of core chips of a semiconductor device according to an embodiment.

FIG. 4 is a block diagram illustrating a semiconductor device according to an embodiment of the present disclosure.

FIG. 5 is a block diagram illustrating a semiconductor device according to an embodiment of the present disclosure.

FIG. 6 and FIG. 7 are diagrams illustrating an embodiment of a stack memory system according to the present disclosure.

### DETAILED DESCRIPTION

Terms such as “vertical,” “horizontal,” “over,” “on,” “left,” “right,” “upward,” “downward,” and other terms implying relative spatial relationship or orientation are utilized only for the purpose of ease of description or reference to a drawing and are not otherwise limiting.

Terms such as “first” and “second” are used to distinguish between various components and do not imply size, order, priority, quantity, or importance of the components. For example, a first component may be referred to as a second component in one example, and the second element may be referred to as a first element in another example.

When one component is identified as “connected” to another component, the components may be connected directly or through an intervening component between the components. When two components are identified as “directly connected,” one component is directly connected to the other component without an intervening component between the two components.

The cross-hatching throughout the figures illustrates corresponding or similar areas between the figures rather than indicating the materials associated with the areas.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

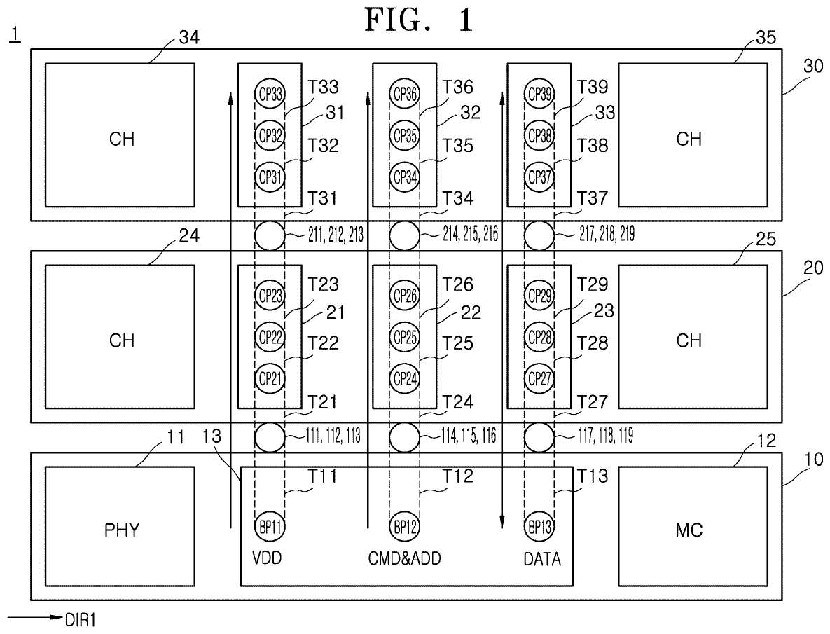

As illustrated in FIG. 1, a semiconductor device 1 according to an embodiment of the present disclosure includes a base chip 10, a first core chip 20, and a second core chip 30. FIG. 1 is a block diagram showing through electrodes T11 to T13, T21 to T29, and T31 to T39 and bumps 111 to 119 and 211 to 219 and interconnections with each other and other components rather than a top view or three-dimensional view of these components for ease of illustration.

The base chip 10 includes an interface circuit PHY 11, a memory controller MC 12, and a pad region 13.

The interface circuit 11 receives, from an external device (not illustrated), a control signal (not illustrated) and external data (not illustrated) that are input to control operations of the first core chip 20 and the second core chip 30. The interface circuit 11 outputs, to the memory controller 12, the control signal and the external data that are received by the interface circuit 11. The interface circuit 11 receives data DATA from the memory controller 12. The interface circuit 11 outputs, to the external device, the data DATA received by the interface circuit 11. The external device may be a processor, a host, or test equipment that controls operations of the first core chip 20 and the second core chip 30. The control signal may be a signal that includes a command CMD and an address ADD that are utilized to perform a write operation and read operation on the first core chip 20 and the second core chip 30. The control signal may be a request signal including a plurality of bits. The external data may be common or normal data stored after the start of write operations on the first core chip 20 and the second core chip 30.

The memory controller 12 applies, to the pad region 13, a power supply voltage VDD supplied to the first core chip 20 and the second core chip 30. The memory controller 12 applies, to a first base pad BP11, the power supply voltage VDD that is supplied to the first core chip 20 and the second core chip 30. The memory controller 12 receives the control signal and the external data from the interface circuit 11. The memory controller 12 generates the command CMD, the address ADD, and the data DATA that are utilized to perform write operations and read operations on the first core chip 20 and the second core chip 30 based on the control signal and external data that are received by the memory controller 12. The memory controller 12 applies the command CMD and the address ADD to the pad region 13 after the start of a write operation and a read operation. The memory controller 12 applies the command CMD and the address ADD to a second base pad BP12. The memory controller 12 applies the data DATA to the pad region 13 after the start of a write operation. The memory controller 12 applies the data DATA to a third base pad BP13 after the start of a write operation. The memory controller 12 receives the data DATA from the pad region 13 after the start of a read operation. The memory controller 12 receives the data DATA from the third base pad BP13 after the start of a read operation. The memory controller 12 outputs, to the interface circuit 11, the data DATA received by the memory controller 12 after the start of a read operation.

The pad region 13 includes the first base pad BP11, the second base pad BP12, the third base pad BP13, a first base through electrode T11, a second base through electrode T12, and a third base through electrode T13.

The pad region 13 is disposed between the interface circuit 11 and the memory controller 12.

The first base pad BP11 is electrically connected to the first base through electrode T11. The first base pad BP11 receives and outputs the power supply voltage VDD to the first base through electrode T11. The word “output” when utilized with respect to a base pad or core pad includes transfer of received voltages or signals.

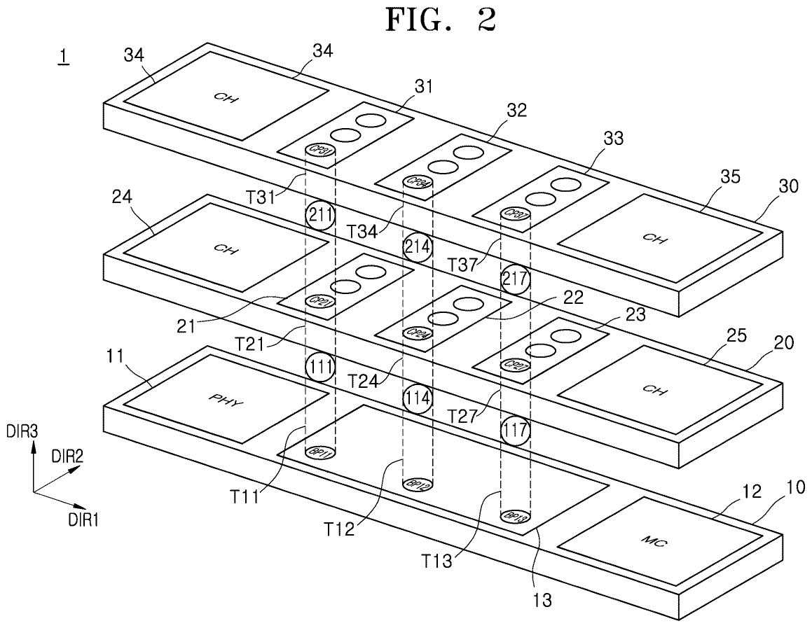

The first base pad BP11 is electrically connected to one of a first bump 111, a second bump 112, and a third bump 113 depending on a location of the first base pad BP11 relative to a corresponding core pad. When the first base pad BP11 is disposed at a corresponding location to the first core pad CP21, the first base pad BP11 is electrically connected to the first bump 111. When a first chip is consecutively disposed with a second chip, a corresponding location for a pad on the first chip includes a location directly above or below a pad on the second chip. For example, a corresponding location for the first base pad BP11 includes the first core pad CP21 on the first core chip 20 that is directly above the first base pad BP11, such as shown in FIG. 2. Corresponding locations include similar physical coordinates on a different chips within the stack of chips. When the first base pad BP11 is disposed at a corresponding location to a second core pad CP22, the first base pad BP11 is electrically connected to the second bump 112. When the first base pad BP11 is disposed at a corresponding location to a third core pad CP23, the first base pad BP11 is electrically connected to the third bump 113.

The second base pad BP12 is electrically connected to the second base through electrode T12. The second base pad BP12 receives and outputs the command CMD and the address ADD through the second base through electrode T12.

The second base pad BP12 is electrically connected to one of a fourth bump 114, a fifth bump 115, and a sixth bump 116 depending on a location of the second base pad BP12 relative to a corresponding core pad. When the second base pad BP12 is disposed at a corresponding location to a fourth core pad CP24, the second base pad BP12 is electrically connected to the fourth bump 114. When the second base pad BP12 is disposed at a corresponding location to a fifth core pad CP25, the second base pad BP12 is electrically connected to the fifth bump 115. When the second base pad BP12 is disposed at a corresponding location to a sixth core pad CP26, the second base pad BP12 is electrically connected to the sixth bump 116.

The third base pad BP13 is electrically connected to the third base through electrode T13. The third base pad BP13 receives and outputs the data DATA through the third base through electrode T13 after the start of a write operation. The third base pad BP13 outputs the data DATA to the memory controller 12 after the start of a read operation.

The third base pad BP13 is electrically connected to one of a seventh bump 117, an eighth bump 118, and a ninth bump 119 depending on a location of the third base pad BP13 relative to a corresponding core pad. When the third base pad BP13 is disposed at a corresponding location to a seventh core pad CP27, the third base pad BP13 is electrically connected to the seventh bump 117. When the third base pad BP13 is disposed at a corresponding location to an eighth core pad CP28, the third base pad BP13 is electrically connected to the eighth bump 118. When the third base pad BP13 is disposed at a corresponding location to a ninth core pad CP29, the third base pad BP13 is electrically connected to the ninth bump 119.

The first base pad BP11, the second base pad BP12, and the third base pad BP13 may be disposed spaced apart from each other by the same distance. The first base through electrode T11, the second base through electrode T12, and the third base through electrode T13 may be disposed spaced apart from each other by the same distance. The first base pad BP11, the second base pad BP12, and the third base pad BP13 may be disposed between the interface circuit 11 and the memory controller 12.

The first core chip 20 is vertically stacked on or over the base chip 10 utilizing the bumps 111 to 119.

The first core chip 20 includes a first path 21, a second path 22, a third path 23, a first channel region CH 24, and a second channel region CH 25.

The first path 21 includes a first core through electrode T21, a second core through electrode T22, a third core through electrode T23, the first core pad CP21, the second core pad CP22, and the third core pad CP23.

The first core through electrode T21 is electrically connected to the first bump 111. The first core pad CP21 is electrically connected to the first core through electrode T21. The first core pad CP21 may receive the power supply voltage VDD and output the power supply voltage VDD to the first channel region 24 and the second channel region 25. When the first base pad BP11 is electrically connected to the first bump 111, the first core pad CP21 receives the power supply voltage VDD from the first base pad BP11 and outputs the power supply voltage VDD to the first channel region 24 and the second channel region 25.

The second core through electrode T22 is electrically connected to the second bump 112. The second core pad CP22 is electrically connected to the second core through electrode T22. The second core pad CP22 may receive the power supply voltage VDD and output the power supply voltage VDD to the first channel region 24 and the second channel region 25. When the first base pad BP11 is electrically connected to the second bump 112, the second core pad CP22 receives the power supply voltage VDD from the first base pad BP11 and outputs the power supply voltage VDD to the first channel region 24 and the second channel region 25.

The third core through electrode T23 is electrically connected to the third bump 113. The third core pad CP23 is electrically connected to the third core through electrode T23. The third core pad CP23 may receive the power supply voltage VDD and output the power supply voltage VDD to the first channel region 24 and the second channel region 25. When the first base pad BP11 is electrically connected to the third bump 113, the third core pad CP23 receives the power supply voltage VDD from the first base pad BP11 and outputs the power supply voltage VDD to the first channel region 24 and the second channel region 25.

The first core through electrode T21, the second core through electrode T22, and the third core through electrode T23 may be disposed spaced apart from each other by the same distance. The first core pad CP21, the second core pad CP22, and the third core pad CP23 may be disposed spaced apart from each other by the same distance.

The first core pad CP21, the second core pad CP22, and the third core pad CP23 that are included in the first path 21 may be implemented with redistribution layers RDLs and electrically connected.

The second path 22 includes a fourth core through electrode T24, a fifth core through electrode T25, a sixth core through electrode T26, the fourth core pad CP24, the fifth core pad CP25, and the sixth core pad CP26.

The fourth core through electrode T24 is electrically connected to the fourth bump 114. The fourth core pad CP24 is electrically connected to the fourth core through electrode T24. The fourth core pad CP24 may receive the command CMD and the address ADD and output the command CMD and the address ADD to the first channel region 24 and the second channel region 25. When the second base pad BP12 is electrically connected to the fourth bump 114, the fourth core pad CP24 receives the command CMD and the address ADD from the second base pad BP12 and outputs the command CMD and the address ADD to the first channel region 24 and the second channel region 25.

The fifth core through electrode T25 is electrically connected to the fifth bump 115. The fifth core pad CP25 is electrically connected to the fifth core through electrode T25. The fifth core pad CP25 may receive the command CMD and the address ADD and output the command CMD and the address ADD to the first channel region 24 and the second channel region 25. When the second base pad BP12 is electrically connected to the fifth bump 115, the fifth core pad CP25 receives the command CMD and the address ADD from the second base pad BP12 and outputs the command CMD and the address ADD to the first channel region 24 and the second channel region 25.

The sixth core through electrode T26 is electrically connected to the sixth bump 116. The sixth core pad CP26 is electrically connected to the sixth core through electrode T26. The sixth core pad CP26 may receive the command CMD and the address ADD and output the command CMD and the address ADD to the first channel region 24 and the second channel region 25. When the second base pad BP12 is electrically connected to the sixth bump 116, the sixth core pad CP26 receives the command CMD and the address ADD from the second base pad BP12 and outputs the command CMD and the address ADD to the first channel region 24 and the second channel region 25.

The fourth core through electrode T24, the fifth core through electrode T25, and the sixth core through electrode T26 may be disposed spaced apart from each other by the same distance. The fourth core pad CP24, the fifth core pad CP25, and the sixth core pad CP26 may be disposed spaced apart from each other by the same distance.

The fourth core pad CP24, the fifth core pad CP25, and the sixth core pad CP26 that are included in the second path 22 may be implemented with redistribution layers RDLs and electrically connected.

The third path 23 includes a seventh core through electrode T27, an eighth core through electrode T28, a ninth core through electrode T29, the seventh core pad CP27, the eighth core pad CP28, and the ninth core pad CP29.

The seventh core through electrode T27 is electrically connected to the seventh bump 117. The seventh core pad CP27 is electrically connected to the seventh core through electrode T27. After the start of a write operation, the seventh core pad CP27 may receive the data DATA and output the data DATA to the first channel region 24 and the second channel region 25. After the start of a write operation, when the third base pad BP13 is electrically connected to the seventh bump 117, the seventh core pad CP27 receives the data DATA from the third base pad BP13 and outputs the data DATA to the first channel region 24 and the second channel region 25. After the start of a read operation, the seventh core pad CP27 may receive the data DATA from the first channel region 24 and the second channel region 25 and output the data DATA. After the start of a read operation, when the third base pad BP13 is electrically connected to the seventh bump 117, the seventh core pad CP27 receives the data DATA from the first channel region 24 and the second channel region 25 and outputs the data DATA to the third base pad BP13.

The eighth core through electrode T28 is electrically connected to the eighth bump 118. The eighth core pad CP28 is electrically connected to the eighth core through electrode T28. After the start of a write operation, the eighth core pad CP28 may receive the data DATA and output the data DATA to the first channel region 24 and the second channel region 25. After the start of a write operation, when the third base pad BP13 is electrically connected to the eighth bump 118, the eighth core pad CP28 receives the data DATA from the third base pad BP13 and outputs the data DATA to the first channel region 24 and the second channel region 25. After the start of a read operation, the eighth core pad CP28 may receive the data DATA from the first channel region 24 and the second channel region 25 and output the data DATA. After the start of a read operation, when the third base pad BP13 is electrically connected to the eighth bump 118, the eighth core pad CP28 receives the data DATA from the first channel region 24 and the second channel region 25 and outputs the data DATA to the third base pad BP13.

The ninth core through electrode T29 is electrically connected to the ninth bump 119. The ninth core pad CP29 is electrically connected to the ninth core through electrode T29. After the start of a write operation, the ninth core pad CP29 may receive the data DATA and output the data DATA to the first channel region 24 and the second channel region 25. After the start of a write operation, when the third base pad BP13 is electrically connected to the ninth bump 119, the ninth core pad CP29 receives the data DATA from the third base pad BP13 and outputs the data DATA to the first channel region 24 and the second channel region 25. After the start of a read operation, the ninth core pad CP29 may receive the data DATA from the first channel region 24 and the second channel region 25 and output the data DATA. After the start of a read operation, when the third base pad BP13 is electrically connected to the ninth bump 119, the ninth core pad CP29 receives the data DATA from the first channel region 24 and the second channel region 25 and outputs the data DATA to the third base pad BP13.

The seventh core through electrode T27, the eighth core through electrode T28, and the ninth core through electrode T29 may be disposed spaced apart from each other by the same distance. The seventh core pad CP27, the eighth core pad CP28, and the ninth core pad CP29 may be disposed spaced apart from each other by the same distance.

The seventh core pad CP27, the eighth core pad CP28, and the ninth core pad CP29 that are included in the third path 23 may be implemented with redistribution layers RDLs and electrically connected.

The first channel region 24 and the second channel region 25 each include a plurality of channels. Each of the plurality of channels included in each of the first channel region 24 and the second channel region 25 stores the data DATA by performing an independent write operation. Each of the plurality of channels included in each of the first channel region 24 and the second channel region 25 outputs the data DATA stored in each channel by performing an independent read operation. The plurality of channels included in each of the first channel region 24 and the second channel region 25 may include four channels or eight channels according to an embodiment.

The first path 21, the second path 22, and the third path 23 are disposed between the first channel region 24 and the second channel region 25. The core pads CP21 to CP29 are disposed between the first channel region 24 and the second channel region 25.

The second core chip 30 is vertically stacked on or over the first core chip 20 utilizing the bumps 211 to 219.

The second core chip 30 includes a fourth path 31, a fifth path 32, a sixth path 33, a third channel region CH 34, and a fourth channel region CH 35.

The fourth path 31 includes a tenth core through electrode T31, an eleventh core through electrode T32, a twelfth core through electrode T33, a tenth core pad CP31, an eleventh core pad CP32, and a twelfth core pad CP33.

The tenth core through electrode T31 is electrically connected to the tenth bump 211. The tenth core pad CP31 is electrically connected to the tenth core through electrode T31. The tenth core pad CP31 may receive the power supply voltage VDD and output the power supply voltage VDD to the third channel region 34 and the fourth channel region 35. When the first base pad BP11 is electrically connected to the first bump 111, the tenth core pad CP31 receives the power supply voltage VDD from the first base pad BP11 and outputs the power supply voltage VDD to the third channel region 34 and the fourth channel region 35.

The eleventh core through electrode T32 is electrically connected to the eleventh bump 212. The eleventh core pad CP32 is electrically connected to the eleventh core through electrode T32. The eleventh core pad CP32 may receive the power supply voltage VDD and output the power supply voltage VDD to the third channel region 34 and the fourth channel region 35. When the first base pad BP11 is electrically connected to the second bump 112, the eleventh core pad CP32 receives the power supply voltage VDD from the first base pad BP11 and outputs the power supply voltage VDD to the third channel region 34 and the fourth channel region 35.

The twelfth core through electrode T33 is electrically connected to the twelfth bump 213. The twelfth core pad CP33 is electrically connected to the twelfth core through electrode T33. The twelfth core pad CP33 may receive the power supply voltage VDD and output the power supply voltage VDD to the third channel region 34 and the fourth channel region 35. When the first base pad BP11 is electrically connected to the third bump 113, the twelfth core pad CP33 receives the power supply voltage VDD from the first base pad BP11 and outputs the power supply voltage VDD to the third channel region 34 and the fourth channel region 35.

The tenth core through electrode T31, the eleventh core through electrode T32, and the twelfth core through electrode T33 may be disposed spaced apart from each other by the same distance. The tenth core pad CP31, the eleventh core pad CP32, and the twelfth core pad CP33 may be disposed spaced apart from each other by the same distance.

The tenth core pad CP31, the eleventh core pad CP32, and the twelfth core pad CP33 that are included in the fourth path 31 may be implemented with redistribution layers RDLs and electrically connected. The tenth core pad CP31, eleventh core pad CP32, and twelfth core pad CP33 of fourth path 31 are disposed at corresponding locations to the first core pad CP21, second core pad CP22, and third core pad CP23 of the first path 21, respectively.

The fifth path 32 includes a thirteenth core through electrode T34, a fourteenth core through electrode T35, a fifteenth core through electrode T36, a thirteenth core pad CP34, a fourteenth core pad CP35, and a fifteenth core pad CP36.

The thirteenth core through electrode T34 is electrically connected to the thirteenth bump 214. The thirteenth core pad CP34 is electrically connected to the thirteenth core through electrode T34. The thirteenth core pad CP34 may receive the command CMD and the address ADD and output the command CMD and the address ADD to the third channel region 34 and the fourth channel region 35. When the second base pad BP12 is electrically connected to the fourth bump 114, the thirteenth core pad CP34 receives the command CMD and the address ADD from the second base pad BP12 and outputs the command CMD and the address ADD to the third channel region 34 and the fourth channel region 35.

The fourteenth core through electrode T35 is electrically connected to the fourteenth bump 215. The fourteenth core pad CP35 is electrically connected to the fourteenth core through electrode T35. The fourteenth core pad CP35 may receive the command CMD and the address ADD and output the command CMD and the address ADD to the third channel region 34 and the fourth channel region 35. When the second base pad BP12 is electrically connected to the fifth bump 115, the fourteenth core pad CP35 receives the command CMD and the address ADD from the second base pad BP12 and outputs the command CMD and the address ADD to the third channel region 34 and the fourth channel region 35.

The fifteenth core through electrode T36 is electrically connected to the fifteenth bump 216. The fifteenth core pad CP36 is electrically connected to the fifteenth core through electrode T36. The fifteenth core pad CP36 may receive the command CMD and the address ADD and output the command CMD and the address ADD to the third channel region 34 and the fourth channel region 35. When the second base pad BP12 is electrically connected to the sixth bump 116, the fifteenth core pad CP36 receives the command CMD and the address ADD from the second base pad BP12 and outputs the command CMD and the address ADD to the third channel region 34 and the fourth channel region 35.

The thirteenth core through electrode T34, the fourteenth core through electrode T35, and the fifteenth core through electrode T36 may be disposed spaced apart from each other by the same distance. The thirteenth core pad CP34, the fourteenth core pad CP35, and the fifteenth core pad CP36 may be disposed spaced apart from each other by the same distance.

The thirteenth core pad CP34, the fourteenth core pad CP35, and the fifteenth core pad CP36 that are included in the fifth path 32 may be implemented with redistribution layers RDLs and electrically connected. The thirteenth core pad CP34, fourteenth core pad CP35, and fifteenth core pad CP36 of the fifth path 32 are disposed at corresponding locations to the fourth core pad CP24, fifth core pad CP25, and sixth core pad CP26 of the second path 22, respectively.

The sixth path 33 includes a sixteenth core through electrode T37, a seventeenth core through electrode T38, an eighteenth core through electrode T39, a sixteenth core pad CP37, a seventeenth core pad CP38, and an eighteenth core pad CP39.

The sixteenth core through electrode T37 is electrically connected to the sixteenth bump 217. The sixteenth core pad CP37 is electrically connected to the sixteenth core through electrode T37. After the start of a write operation, the sixteenth core pad CP37 may receive the data DATA and output the data DATA to the third channel region 34 and the fourth channel region 35. After the start of a write operation, when the third base pad BP13 is electrically connected to the seventh bump 117, the sixteenth core pad CP37 receives the data DATA from the third base pad BP13 and outputs the data DATA to the third channel region 34 and the fourth channel region 35. After the start of a read operation, the sixteenth core pad CP37 may receive the data DATA from the third channel region 34 and the fourth channel region 35 and output the data DATA. After the start of a read operation, when the third base pad BP13 is electrically connected to the seventh bump 117, the sixteenth core pad CP37 receives the data DATA from the third channel region 34 and the fourth channel region 35 and outputs the data DATA to the third base pad BP13.

The seventeenth core through electrode T38 is electrically connected to the seventeenth bump 218. The seventeenth core pad CP38 is electrically connected to the seventeenth core through electrode T38. After the start of a write operation, the seventeenth core pad CP38 may receive the data DATA and output the data DATA to the third channel region 34 and the fourth channel region 35. After the start of a write operation, when the third base pad BP13 is electrically connected to the eighth bump 118, the seventeenth core pad CP38 receives the data DATA from the third base pad BP13 and outputs the data DATA to the third channel region 34 and the fourth channel region 35. After the start of a read operation, the seventeenth core pad CP38 may receive the data DATA from the third channel region 34 and the fourth channel region 35 and output the data DATA. After the start of a read operation, when the third base pad BP13 is electrically connected to the eighth bump 118, the seventeenth core pad CP38 receives the data DATA from the third channel region 34 and the fourth channel region 35 and outputs the data DATA to the third base pad BP13.

The eighteenth core through electrode T39 is electrically connected to the eighteenth bump 219. The eighteenth core pad CP39 is electrically connected to the eighteenth core through electrode T39. After the start of a write operation, the eighteenth core pad CP39 may receive the data DATA and output the data DATA to the third channel region 34 and the fourth channel region 35. After the start of a write operation, when the third base pad BP13 is electrically connected to the ninth bump 119, the eighteenth core pad CP39 receives the data DATA from the third base pad BP13 and outputs the data DATA to the third channel region 34 and the fourth channel region 35. After the start of a read operation, the eighteenth core pad CP39 may receive the data DATA from the third channel region 34 and the fourth channel region 35 and output the data DATA. After the start of a read operation, when the third base pad BP13 is electrically connected to the ninth bump 119, the eighteenth core pad CP39 receives the data DATA from the third channel region 34 and the fourth channel region 35 and outputs the data DATA to the third base pad BP13.

The sixteenth core through electrode T37, the seventeenth core through electrode T38, and the eighteenth core through electrode T39 may be disposed spaced apart from each other by the same distance. The sixteenth core pad CP37, the seventeenth core pad CP38, and the eighteenth core pad CP39 may be disposed spaced apart from each other by the same distance.

The sixteenth core pad CP37, the seventeenth core pad CP38, and the eighteenth core pad CP39 that are included in the sixth path 33 may be implemented with redistribution layers RDLs and electrically connected. The sixteenth core pad CP37, seventeenth core pad CP38, and eighteenth core pad CP39 of the sixth path 33 are disposed at corresponding locations to the seventh core pad CP27, eighth core pad CP28, and ninth core pad CP29 of the third path 23, respectively.

Each of the third channel region 34 and the fourth channel region 35 includes a plurality of channels. Each of the plurality of channels included in each of the third channel region 34 and the fourth channel region 35 stores the data DATA by performing an independent write operation. Each of the plurality of channels included in each of the third channel region 34 and the fourth channel region 35 outputs the data DATA stored in each channel by performing an independent read operation. The plurality of channels included in each of the third channel region 34 and the fourth channel region 35 may include four channels or eight channels according to an embodiment.

The fourth path 31, the fifth path 32, and the sixth path 33 are disposed between the third channel region 34 and the fourth channel region 35. The core pads CP31 to CP39 are disposed between the third channel region 34 and the fourth channel region 35.

Although the semiconductor device 1 illustrated in FIG. 1 includes the base chip 10, the first core chip 20, and the second core chip 30 in a vertically stacked arrangement, different quantities of core chips, such as 4, 8, and 12, are stacked on or over the base chip 10 according to different embodiments.

The base through electrodes T11 to T13, the core through electrodes T21 to T29, and the core through electrodes T31 to T39 illustrated in FIG. 1 may each be implemented as a cylinder made of conductive material such that the base through electrodes T11 to T13, the core through electrodes T21 to T29, and the core through electrode T31 to T39 are vertically stacked through the base chip 10, the first core chip 20, and the second core chip 30. The bumps 111 to 119 and 211 to 219 may each be implemented in the form of a ball made of conductive material such that the bumps 111 to 219 may be directly connected to a circuit board.

FIG. 2 is a diagram illustrating connections between the pads of the base chip 10 and the pads of the first core chip 20 and the second core chip 30, for example, as illustrated in FIG. 1 according to an embodiment. The connections between the pads of the base chip 10 and the pads of the first and second core chips 20 and 30 according to the first embodiment of the present disclosure are described with reference to FIG. 2. An example is described where the first base pad BP11, the second base pad BP12, and the third base pad BP13 are disposed at corresponding locations to the first core pad CP21, the fourth core pad CP24, and the seventh core pad CP27, respectively. The first base pad BP11, the second base pad BP12, and the third base pad BP13 are distributed in a first direction DIR 1. The first core pad CP21, the second core pad CP22, and the third core pad CP23 are distributed in a second direction DIR 2. The base chip 10, the first core chip 20, and the second core chip 30 are shown spaced apart in a third direction DIR 3.

The first base pad BP11, the second base pad BP12, and the third base pad BP13 are disposed between the interface circuit 11 and the memory controller 12.

The first base pad BP11 is electrically connected to the first base through electrode T11 and the first bump 111. The first base pad BP11 receives the power supply voltage VDD and outputs the power supply voltage VDD to the first base through electrode T11.

The second base pad BP12 is electrically connected to the second base through electrode T12 and the fourth bump 114. The second base pad BP12 receives the command CMD and the address ADD and outputs the command CMD and the address ADD through the second base through electrode T12.

The third base pad BP13 is electrically connected to the third base through electrode T13 and the seventh bump 117. After the start of a write operation, the third base pad BP13 receives the data DATA and outputs the data DATA through the third base through electrode T13. After the start of a read operation, the third base pad BP13 receives the data DATA through the third base through electrode T13 and outputs the data DATA to the memory controller 12.

The first core pad CP21, the fourth core pad CP24, and the seventh core pad CP27 are disposed between the first channel region 24 and the second channel region 25.

The first core pad CP21 is electrically connected to the first core through electrode T21 and the first bump 111. The first core pad CP21 receives the power supply voltage VDD to the first core through electrode T21 and the first bump 111 and outputs the power supply voltage VDD to the first channel region 24 and the second channel region 25. When the first base pad BP11 is electrically connected to the first bump 111, the first core pad CP21 receives the power supply voltage VDD from the first base pad BP11 and outputs the power supply voltage VDD to the first channel region 24 and the second channel region 25.

The fourth core pad CP24 is electrically connected to the fourth core through electrode T24 and the fourth bump 114. The fourth core pad CP24 receives the command CMD and the address ADD through the fourth core through electrode T24 and the fourth bump 114 and outputs the command CMD and the address ADD to the first channel region 24 and the second channel region 25. When the second base pad BP12 is electrically connected to the fourth bump 114, the fourth core pad CP24 receives the command CMD and the address ADD from the second base pad BP12 and outputs the command CMD and the address ADD to the first channel region 24 and the second channel region 25.

The seventh core pad CP27 is electrically connected to the seventh core through electrode T27 and the seventh bump 117. After the start of a write operation, the seventh core pad CP27 receives the data DATA through the seventh core through electrode T27 and the seventh bump 117 and outputs the data DATA to the first channel region 24 and the second channel region 25. After the start of a write operation, when the third base pad BP13 is electrically connected to the seventh bump 117, the seventh core pad CP27 receives the data DATA from the third base pad BP13 and outputs the data DATA to the first channel region 24 and the second channel region 25. After the start of a read operation, the seventh core pad CP27 receives the data DATA from the first channel region 24 and the second channel region 25 and outputs the data DATA through the seventh core through electrode T27 and the seventh bump 117. After the start of a read operation, when the third base pad BP13 is electrically connected to the seventh bump 117, the seventh core pad CP27 outputs the data DATA to the third base pad BP13 through the seventh core through electrode T27 and the seventh bump 117.

The tenth core pad CP31, the thirteenth core pad CP34, and the sixteenth core pad CP37 are disposed between the third channel region 34 and the fourth channel region 35.

The tenth core pad CP31 is electrically connected to the tenth core through electrode T31 and the tenth bump 211. The tenth core pad CP31 receives the power supply voltage VDD to the tenth core through electrode T31 and the tenth bump 211 and outputs the power supply voltage VDD to the third channel region 34 and the fourth channel region 35. When the first base pad BP11 is electrically connected to the first bump 111, the tenth core pad CP31 receives the power supply voltage VDD from the first base pad BP11 and outputs the power supply voltage VDD to the third channel region 34 and the fourth channel region 35.

The thirteenth core pad CP34 is electrically connected to the thirteenth core through electrode T34 and the thirteenth bump 214. The thirteenth core pad CP34 receives the command CMD and the address ADD through the thirteenth core through electrode T34 and the thirteenth bump 214 and outputs the command CMD and the address ADD to the third channel region 34 and the fourth channel region 35. When the second base pad BP12 is electrically connected to the fourth bump 114, the thirteenth core pad CP34 receives the command CMD and the address ADD from the second base pad BP12 and outputs the command CMD and the address ADD to the third channel region 34 and the fourth channel region 35.

The sixteenth core pad CP37 is electrically connected to the sixteenth core through electrode T37 and the sixteenth bump 217. After the start of a write operation, the sixteenth core pad CP37 receives the data DATA through the sixteenth core through electrode T37 and the sixteenth bump 217 and outputs the data DATA to the third channel region 34 and the fourth channel region 35. After the start of a write operation, when the third base pad BP13 is electrically connected to the seventh bump 117, the sixteenth core pad CP37 receives the data DATA from the third base pad BP13 and outputs the data DATA to the third channel region 34 and the fourth channel region 35. After the start of a read operation, the sixteenth core pad CP37 receives the data DATA from the third channel region 34 and the fourth channel region 35 and outputs the data DATA through the sixteenth core through electrode T37 and the sixteenth bump 217. After the start of a read operation, when the third base pad BP13 is electrically connected to the seventh bump 117, the sixteenth core pad CP37 outputs the data DATA to the third base pad BP13 through the sixteenth core through electrode T37 and the sixteenth bump 217.

As described for the semiconductor device 1 according to an embodiment of the present disclosure, the plurality of pads included in the first core chip 20 and the second core chip 30 is electrically connected, and a pad of the base chip 10 and one of the plurality of pads of the core chips 20 and 30 are connected. Accordingly, the base chip and the core chips including pads at different locations can be electrically connected. In the semiconductor device 1, wherever a pad of the base chip 10 is located, the base chip 10 and the core chips 20 and 30 including pads at various different locations can be electrically connected by connecting the pad of the base chip 10 and one of the plurality of pads of the first core chip 20 and the second core chip 30.

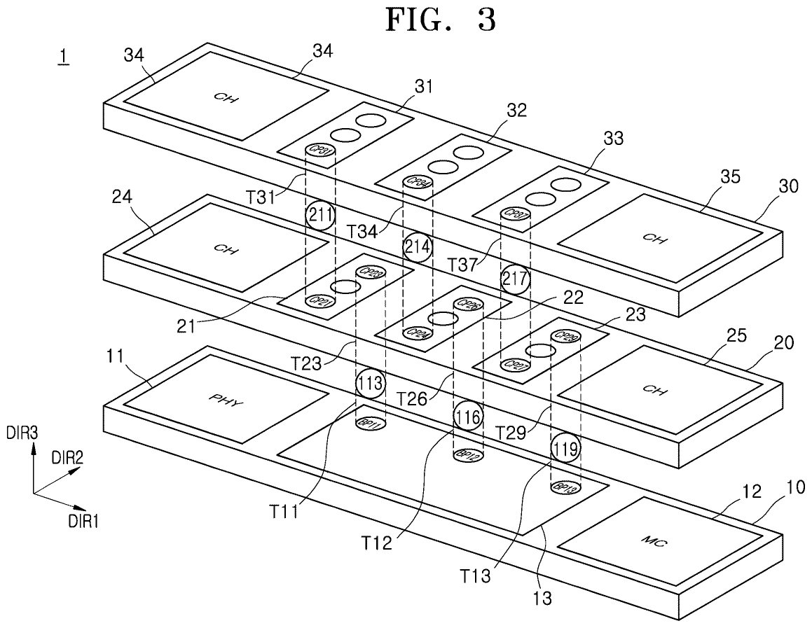

FIG. 3 is a diagram illustrating connections between pads of a base chip and pads of core chips, for example, as illustrated in FIG. 1 according to an embodiment. The connections between the pads of the base chip and the pads of the core chips according to a second embodiment of the present disclosure are described with reference to FIG. 3. An example is described where the first base pad BP11, the second base pad BP12, and the third base pad BP13 are disposed at corresponding locations to the third core pad CP23, the sixth core pad CP26, and the ninth core pad CP29, respectively.

The first base pad BP11, the second base pad BP12, and the third base pad BP13 are disposed between the interface circuit 11 and the memory controller 12.

The first base pad BP11 is electrically connected to the first base through electrode T11 and the third bump 113. The first base pad BP11 receives the power supply voltage VDD and outputs the power supply voltage VDD to the first base through electrode T11.

The second base pad BP12 is electrically connected to the second base through electrode T12 and the sixth bump 116. The second base pad BP12 receives the command CMD and the address ADD and outputs the command CMD and the address ADD through the second base through electrode T12.

The third base pad BP13 is electrically connected to the third base through electrode T13 and the ninth bump 119. After the start of a write operation, the third base pad BP13 receives the data DATA and outputs the data DATA through the third base through electrode T13. After the start of a read operation, the third base pad BP13 receives the data DATA through the third base through electrode T13 and outputs the data DATA to the memory controller 12.

The third core pad CP23, the sixth core pad CP26, and the ninth core pad CP29 are disposed between the first channel region 24 and the second channel region 25.

The third core pad CP23 is electrically connected to the third core through electrode T23 and the third bump 113. The third core pad CP23 receives the power supply voltage VDD to the third core through electrode T23 and the third bump 113 and outputs the power supply voltage VDD to the first channel region 24 and the second channel region 25. When the first base pad BP11 is electrically connected to the third bump 113, the third core pad CP23 receives the power supply voltage VDD from the first base pad BP11 and outputs the power supply voltage VDD to the first channel region 24 and the second channel region 25. The third core pad CP23 is electrically connected to the first core pad CP21. The first core pad CP21 is electrically connected to the tenth bump 211.

The sixth core pad CP26 is electrically connected to the sixth core through electrode T26 and the sixth bump 116. The sixth core pad CP26 receives the command CMD and the address ADD through the sixth core through electrode T26 and the sixth bump 116 and outputs the command CMD and the address ADD to the first channel region 24 and the second channel region 25. When the second base pad BP12 is electrically connected to the sixth bump 116, the sixth core pad CP26 receives the command CMD and the address ADD from the second base pad BP12 and outputs the command CMD and the address ADD to the first channel region 24 and the second channel region 25. The sixth core pad CP26 is electrically connected to the fourth core pad CP24. The fourth core pad CP24 is electrically connected to the thirteenth bump 214.

The ninth core pad CP29 is electrically connected to the ninth core through electrode T29 and the ninth bump 119. After the start of a write operation, the ninth core pad CP29 receives the data DATA through the ninth core through electrode T29 and the ninth bump 119 and outputs the data DATA to the first channel region 24 and the second channel region 25. After the start of a write operation, when the third base pad BP13 is electrically connected to the ninth bump 119, the ninth core pad CP29 receives the data DATA from the third base pad BP13 and outputs the data DATA to the first channel region 24 and the second channel region 25. After the start of a read operation, the ninth core pad CP29 receives the data DATA from the first channel region 24 and the second channel region 25 and outputs the data DATA through the ninth core through electrode T29 and the ninth bump 119. After the start of a read operation, when the third base pad BP13 is electrically connected to the ninth bump 119, the ninth core pad CP29 outputs the data DATA to the third base pad BP13 through the ninth core through electrode T29 and the ninth bump 119. The ninth core pad CP29 is electrically connected to the seventh core pad CP27. The seventh core pad CP27 is electrically connected to the sixteenth bump 217.

The tenth core pad CP31, the thirteenth core pad CP34, and the sixteenth core pad CP37 are disposed between the third channel region 34 and the fourth channel region 35.

The tenth core pad CP31 is electrically connected to the tenth core through electrode T31 and the tenth bump 211. The tenth core pad CP31 receives the power supply voltage VDD to the tenth core through electrode T31 and the tenth bump 211 and outputs the power supply voltage VDD to the third channel region 34 and the fourth channel region 35. When the first base pad BP11 is electrically connected to the third bump 113, the tenth core pad CP31 receives the power supply voltage VDD from the first base pad BP11 and outputs the power supply voltage VDD to the third channel region 34 and the fourth channel region 35.

The thirteenth core pad CP34 is electrically connected to the thirteenth core through electrode T34 and the thirteenth bump 214. The thirteenth core pad CP34 receives the command CMD and the address ADD through the thirteenth core through electrode T34 and the thirteenth bump 214 and outputs the command CMD and the address ADD to the third channel region 34 and the fourth channel region 35. When the second base pad BP12 is electrically connected to the sixth bump 116, the thirteenth core pad CP34 receives the command CMD and the address ADD from the second base pad BP12 and outputs the command CMD and the address ADD to the third channel region 34 and the fourth channel region 35.

The sixteenth core pad CP37 is electrically connected to the sixteenth core through electrode T37 and the sixteenth bump 217. After the start of a write operation, the sixteenth core pad CP37 receives the data DATA through the sixteenth core through electrode T37 and the sixteenth bump 217 and outputs the data DATA to the third channel region 34 and the fourth channel region 35. After the start of a write operation, when the third base pad BP13 is electrically connected to the ninth bump 119, the sixteenth core pad CP37, receives the data DATA from the third base pad BP13 and outputs the data DATA to the third channel region 34 and the fourth channel region 35. After the start of a read operation, the sixteenth core pad CP37 receives the data DATA from the third channel region 34 and the fourth channel region 35 and outputs the data DATA through the sixteenth core through electrode T37 and the sixteenth bump 217. After the start of a read operation, when the third base pad BP13 is electrically connected to the seventh bump 117, the sixteenth core pad CP37 outputs the data DATA to the third base pad BP13 through the sixteenth core through electrode T37 and the sixteenth bump 217.

As described for the semiconductor device 1 according to an embodiment of the present disclosure, the plurality of pads included in the first core chip 20 and the second core chip 30 is electrically connected, and a pad of the base chip 10 and one of the plurality of pads of the first core chip 20 and the second core chip 30 are connected. Accordingly, pads located at different positions on the base chip 10 and the core chips 20 and 30 can be electrically connected. In the semiconductor device 1, wherever a pad of the base chip 10 is located, the base chip 10 and the core chips 20 and 30 including pads at various different locations can be electrically connected by connecting the pad of the base chip 10 and one of the plurality of pads of the first core chip 20 and the second core chip 30.

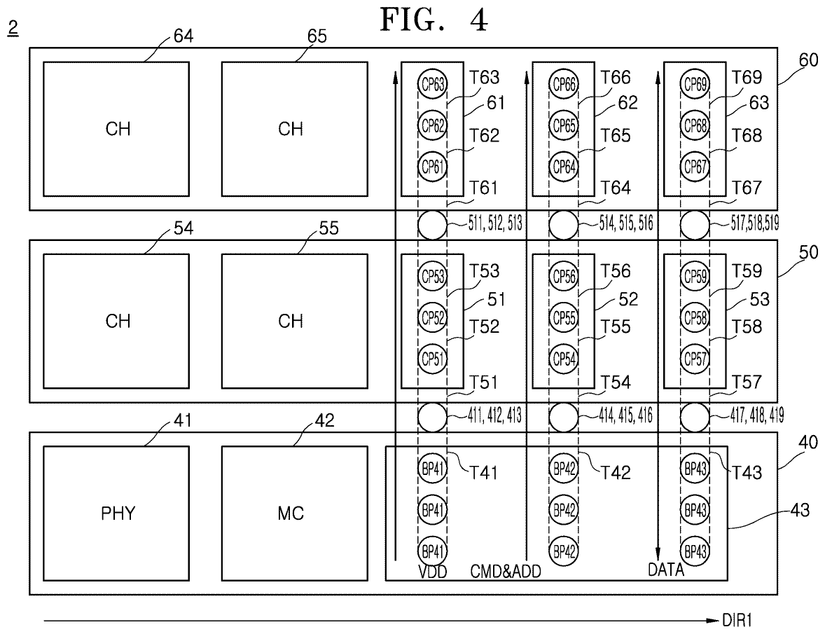

FIG. 4 is a block diagram illustrating a semiconductor device 2 according to an embodiment of the present disclosure. As illustrated in FIG. 4, the semiconductor device 2 according to an embodiment of the present disclosure includes a base chip 40, a first core chip 50, and a second core chip 60. FIG. 4 is a block diagram showing through electrodes T41 to T43, T51 to T59, and T61 to T69 and bumps 411 to 419 and 511 to 619 and interconnections with each other and other components rather than a top view or three-dimensional view of these components for ease of illustration.

The base chip 40 includes an interface circuit PHY 41, a memory controller MC 42, and a pad region 43.

The interface circuit 41 and the memory controller 42 perform similar operations as performed by the interface circuit 11 and the memory controller 12, respectively, as illustrated in FIG. 1.

The pad region 43 includes a first base pad BP41, a second base pad BP42, and a third base pad BP43. Three possible locations for each of the first base pad BP41, the second base pad BP42, and the third base pad BP43 are shown in this example.

The pad region 43 is disposed with the interface circuit 41 and the memory controller 42 along a first direction DIR 1, for example, as horizontally with respect to the drawing.

The first base pad BP41 is electrically connected to a first base through electrode T41. The first base pad BP41 receives a power supply voltage VDD and outputs the power supply voltage VDD to the first base through electrode T41.

The first base pad BP41 is electrically connected to one of a first bump 411, a second bump 412, and a third bump 413 depending on a location of the first base pad BP41 relative to a corresponding core pad. When the first base pad BP41 is disposed at a corresponding location to a first core pad CP51, the first base pad BP11 is electrically connected to the first bump 411. When the first base pad BP41 is disposed at a corresponding location to a second core pad CP52, the first base pad BP41 is electrically connected to the second bump 412. When the first base pad BP41 is disposed at a corresponding location to a third core pad CP53, the first base pad BP41 is electrically connected to the third bump 413.

The second base pad BP42 is electrically connected to a second base through electrode T42. The second base pad BP42 receives a command CMD and an address ADD and outputs the command CMD and the address ADD through the second base through electrode T42.

The second base pad BP42 is electrically connected to one of a fourth bump 414, a fifth bump 415, and a sixth bump 416 depending on a location of the second base pad BP42 relative to a corresponding core pad. When the second base pad BP42 is disposed at a corresponding location to a fourth core pad CP54, the second base pad BP42 is electrically connected to the fourth bump 414. When the second base pad BP42 is disposed at a corresponding location to a fifth core pad CP55, the second base pad BP42 is electrically connected to the fifth bump 415. When the second base pad BP42 is disposed at a corresponding location as a sixth core pad CP56, the second base pad BP42 is electrically connected to the sixth bump 416.

The third base pad BP43 is electrically connected to a third base through electrode T43. After the start of a write operation, the third base pad BP43 receives data DATA and outputs the data DATA through the third base through electrode T43. After the start of a read operation, the third base pad BP43 receives the data DATA through the third base through electrode T43 and outputs the data DATA to the memory controller 42.

The third base pad BP43 is electrically connected to one of a seventh bump 417, an eighth bump 418, and a ninth bump 419 depending on a location of the third base pad BP43 relative to a corresponding core pad. When the third base pad BP43 is disposed at a corresponding location to a seventh core pad CP57, the third base pad BP43 is electrically connected to the seventh bump 417. When the third base pad BP43 is disposed at a corresponding location to an eighth core pad CP58, the third base pad BP43 is electrically connected to the eighth bump 418. When the third base pad BP43 is disposed at a corresponding location to a ninth core pad CP59, the third base pad BP43 is electrically connected to the ninth bump 419.

The first base pad BP41, the second base pad BP42, and the third base pad BP43 may be disposed spaced apart from each other by the same distance. The first base through electrode T41, the second base through electrode T42, and the third base through electrode T43 may be disposed spaced apart from each other by the same distance. The first base pad BP41, the second base pad BP42, and the third base pad BP43 are disposed along the first direction with the interface circuit 41 and the memory controller 42.

The first core chip 50 is vertically stacked on or over the base chip 40 utilizing the bumps 411 to 419.

The first core chip 50 includes a first path 51, a second path 52, a third path 53, a first channel region CH 54, and a second channel region CH 55.

The first path 51 includes a first core through electrode T51, a second core through electrode T52, a third core through electrode T53, the first core pad CP51, the second core pad CP52, and the third core pad CP53.

The first core pad CP51, the second core pad CP52, and the third core pad CP53 that are included in the first path 51 may be implemented with redistribution layers RDLs and electrically connected.

The structure in which the first bump 411, the second bump 412, the third bump 413, the first core through electrode T51, the second core through electrode T52, the third core through electrode T53, the first core pad CP51, the second core pad CP52, and the third core pad CP53 are electrically connected is similar to the structure in which the first bump 111, the second bump 112, the third bump 113, the first core through electrode T21, the second core through electrode T22, the third core through electrode T23, the first core pad CP21, the second core pad CP22, and the third core pad CP23 illustrated in FIG. 1 are electrically connected.

The second path 52 includes a fourth core through electrode T54, a fifth core through electrode T55, a sixth core through electrode T56, the fourth core pad CP54, the fifth core pad CP55, and the sixth core pad CP56.

The fourth core pad CP54, the fifth core pad CP55, and the sixth core pad CP56 that are included in the second path 52 may be implemented with redistribution layers RDLs and electrically connected.

The structure in which the fourth bump 414, the fifth bump 415, the sixth bump 416, the fourth core through electrode T54, the fifth core through electrode T55, the sixth core through electrode T56, the fourth core pad CP54, the fifth core pad CP55, and the sixth core pad CP56 are electrically connected similar to the structure in which the fourth bump 114, the fifth bump 115, the sixth bump 116, the fourth core through electrode T24, the fifth core through electrode T25, the sixth core through electrode T26, the fourth core pad CP24, the fifth core pad CP25, and the sixth core pad CP26 illustrated in FIG. 1 are electrically connected.

The third path 53 includes a seventh core through electrode T57, an eighth core through electrode T58, a ninth core through electrode T59, the seventh core pad CP57, the eighth core pad CP58, and the ninth core pad CP59.

The seventh core pad CP57, the eighth core pad CP58, and the ninth core pad CP59 that are included in the third path 53 may be implemented with redistribution layers RDLs and electrically connected.

The structure in which the seventh bump 417, the eighth bump 418, the ninth bump 419, the seventh core through electrode T57, the eighth core through electrode T58, the ninth core through electrode T59, the seventh core pad CP57, the eighth core pad CP58, and the ninth core pad CP59 are electrically connected is similar to the structure in which the seventh bump 117, the eighth bump 118, the ninth bump 119, the seventh core through electrode T27, the eighth core through electrode T28, the ninth core through electrode T29, the seventh core pad CP27, the eighth core pad CP28, and the ninth core pad CP29 illustrated in FIG. 1 are electrically connected.

The first channel region 54 and the second channel region 55 perform similar operations as performed by the first channel region 24 and the second channel region 25, respectively, as illustrated in FIG. 1.

The first path 51, the second path 52, and the third path 53 are disposed spaced apart in the first direction DIR 1 with the first channel region 54 and the second channel region 55.

The second core chip 60 are vertically stacked on or over the first core chip 50 utilizing the bumps 511 to 519.

The second core chip 60 includes a fourth path 61, a fifth path 62, a sixth path 63, a third channel region CH 64, and a fourth channel region CH 65.

The fourth path 61 includes a tenth core through electrode T61, an eleventh core through electrode T62, a twelfth core through electrode T63, a tenth core pad CP61, an eleventh core pad CP62, and a twelfth core pad CP63.

The tenth core pad CP61, the eleventh core pad CP62, and the twelfth core pad CP63 that are included in the fourth path 61 may be implemented with redistribution layers RDLs and electrically connected.

The structure in which the tenth bump 511, the eleventh bump 512, the twelfth bump 513, the tenth core through electrode T61, the eleventh core through electrode T62, the twelfth core through electrode T63, the tenth core pad CP61, the eleventh core pad CP62, and the twelfth core pad CP63 are electrically connected is similar to the structure in which the tenth bump 211, the eleventh bump 212, the twelfth bump 213, the tenth core through electrode T31, the eleventh core through electrode T32, the twelfth core through electrode T33, the tenth core pad CP31, the eleventh core pad CP32, and the twelfth core pad CP33 illustrated in FIG. 1 are electrically connected.

The fifth path 62 includes a thirteenth core through electrode T64, a fourteenth core through electrode T65, a fifteenth core through electrode T66, a thirteenth core pad CP64, a fourteenth core pad CP65, and a fifteenth core pad CP66.

The thirteenth core pad CP64, the fourteenth core pad CP65, and the fifteenth core pad CP66 that are included in the fifth path 62 may be implemented with redistribution layers RDLs and electrically connected.

The structure in which the thirteenth bump 514, the fourteenth bump 515, the fifteenth bump 516, the thirteenth core through electrode T64, the fourteenth core through electrode T65, the fifteenth core through electrode T66, the thirteenth core pad CP64, the fourteenth core pad CP65, and the fifteenth core pad CP66 are electrically connected is similar to the structure in which the thirteenth bump 214, the fourteenth bump 215, the fifteenth bump 216, the thirteenth core through electrode T34, the fourteenth core through electrode T35, the fifteenth core through electrode T56, the thirteenth core pad CP34, the fourteenth core pad CP35, and the fifteenth core pad CP36 illustrated in FIG. 1 are electrically connected.

The sixth path 63 includes a sixteenth core through electrode T67, a seventeenth core through electrode T68, an eighteenth core through electrode T69, a sixteenth core pad CP67, a seventeenth core pad CP68, and an eighteenth core pad CP69.

The sixteenth core pad CP67, the seventeenth core pad CP68, and the eighteenth core pad CP69 that are included in the third path 63 may be implemented with redistribution layers RDLs and electrically connected.

The structure in which the sixteenth bump 517, the seventeenth bump 518, the eighteenth bump 519, the sixteenth core through electrode T67, the seventeenth core through electrode T68, the eighteenth core through electrode T69, the sixteenth core pad CP67, the seventeenth core pad CP68, and the eighteenth core pad CP69 are electrically connected is similar to the structure in which the sixteenth bump 217, the seventeenth bump 218, the eighteenth bump 219, the sixteenth core through electrode T37, the seventeenth core through electrode T38, the eighteenth core through electrode T39, the sixteenth core pad CP37, the seventeenth core pad CP38, and the eighteenth core pad CP39 illustrated in FIG. 1 are electrically connected.

The third channel region 64 and the fourth channel region 65 perform similar operations as performed by the third channel region 34 and the fourth channel region 35, respectively, as illustrated in FIG. 1.

The fourth path 61, the fifth path 62, and the sixth path 63 are disposed spaced apart in the first direction DIR 1 with the third channel region 64 and the fourth channel region 65.

The structure in which the base pads BP41 to BP43 and the core pads CP51 to CP69 illustrated in FIG. 4 are electrically connected is similar the structure in which the base pads BP11 to BP13 and the core pads CP21 to CP39 illustrated in FIG. 2 and FIG. 3 are electrically connected.

The base through electrodes T41 to T43, the core through electrodes T51 to T59, and the core through electrodes T61 to T69 illustrated in FIG. 4 may each be implemented as a cylinder made of conductive material such that the base through electrodes T41 to T43, the core through electrodes T51 to T59, and the core through electrodes T61 to T69 are vertically stacked through the base chip 40, the first core chip 50, and the second core chip 60. The bumps 411 to 419 and 511 to 519 may each be implemented in the form of a ball made of conductive material such that the bumps 411 to 419 and 511 to 519 may be directly connected to a printed circuit board.

Although the semiconductor device 2 illustrated in FIG. 4 includes the base chip 40, the first core chip 50, and the second core chip 60 in a vertically stacked arrangement, different quantities of core chips, such as 4, 8, and 12, are stacked on or over the base chip 10 according to different embodiments.

As described for the semiconductor device 2 according to an embodiment of the present disclosure, the plurality of pads included in the core chips 50 and 60 is electrically connected, and a pad of the base chip 40 and one of the plurality of pads of the first core chip 50 and the second core chip 60 are connected. Accordingly, pads located at different positions on the base chip 40 and the core chips 50 and 60 can be electrically connected. In the semiconductor device 2, wherever a pad of the base chip 40 is located, the base chip 40 and the core chips 50 and 60 including pads at various different locations can be electrically connected by connecting the pad of the base chip 40 and one of the plurality of pads of the first core chip 50 and the second core chip 60.

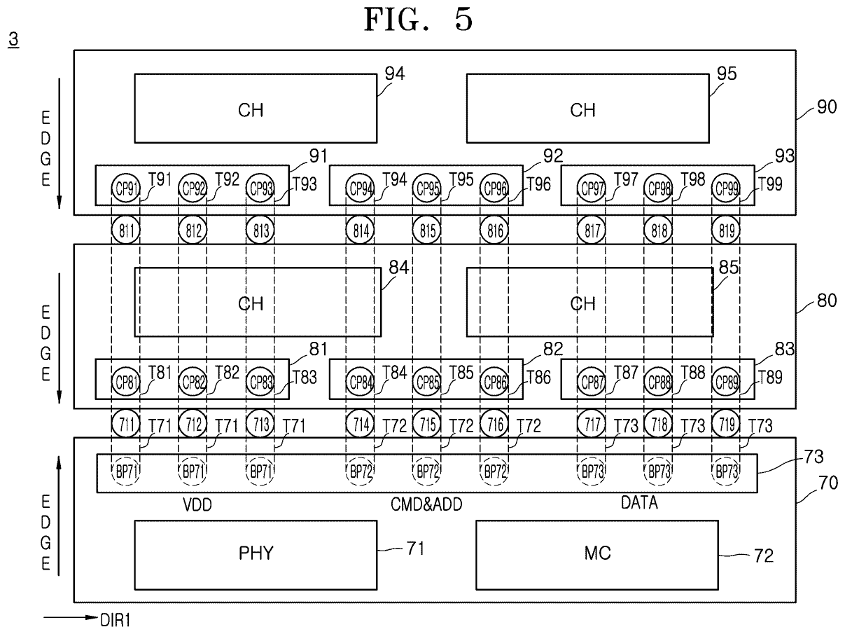

FIG. 5 is a block diagram illustrating a semiconductor device according to an embodiment of the present disclosure. As illustrated in FIG. 5, the semiconductor device 3 according to an embodiment of the present disclosure includes a base chip 70, a first core chip 80, and a second core chip 90. FIG. 5 is a block diagram showing through electrodes T71 to T73, T81 to T89, and T91 to T99 and bumps 711 to 719 and 811 to 819 and interconnections with each other and other components rather than a top view or three-dimensional view of these components for ease of illustration.

The base chip 70 includes an interface circuit PHY 71, a memory controller MC 72, and a pad region 73.

The interface circuit 71 and the memory controller 72 perform similar operations as performed by the interface circuit 11 and the memory controller 12, respectively, as illustrated in FIG. 1.

The pad region 73 includes a first base pad BP71, a second base pad BP72, and a third base pad BP73. Three possible locations for each of the first base pad BP71, the second base pad BP72, and the third base pad BP73 are shown in this example.

The pad region 73 is disposed between a first surface of the base chip 70 and the interface circuit 71 and the memory controller 72 that are disposed, for example, along the first direction DIR 1. The first surface of the base chip 70 may be a top surface or a bottom surface of the base chip 70 relative to the orientation of FIG. 5. The pad region 73 may be disposed near an edge of the first surface of the base chip 70.

A first base pad BP71 is electrically connected to a first base through electrode T71. The first base pad BP71 receives a power supply voltage VDD and output the power supply voltage VDD to the first base through electrode T71.

The first base pad BP71 is electrically connected to one of a first bump 711, a second bump 712, and a third bump 713 depending on a location of the first base pad BP71 relative to a corresponding core pad. When the first base pad BP71 is disposed at a corresponding location to a first core pad CP81, the first base pad BP71 is electrically connected to the first bump 711. When the first base pad BP71 is disposed at a corresponding location to a second core pad CP82, the first base pad BP71 is electrically connected to the second bump 712. When the first base pad BP71 is disposed at a corresponding location as a third core pad CP83, the first base pad BP71 is electrically connected to the third bump 713.

The second base pad BP72 is electrically connected to a second base through electrode T72. The second base pad BP72 receives a command CMD and an address ADD and outputs the command CMD and the address ADD through the second base through electrode T72.

The second base pad BP72 is electrically connected to one of a fourth bump 714, a fifth bump 715, and a sixth bump 716 depending on a location of the second base pad BP72 relative to a corresponding core pad. When the second base pad BP72 is disposed at a corresponding location to a fourth core pad CP84, the second base pad BP72 is electrically connected to the fourth bump 714. When the second base pad BP72 is disposed at a corresponding location to a fifth core pad CP85, the second base pad BP72 is electrically connected to the fifth bump 715. When the second base pad BP72 is disposed at a corresponding location to a sixth core pad CP86, the second base pad BP72 is electrically connected to the sixth bump 716.

The third base pad BP73 is electrically connected to a third base through electrode T73. After the start of a write operation, the third base pad BP73 receives data DATA and outputs the data DATA through the third base through electrode T73. After the start of a read operation, the third base pad BP73 receives the data DATA through the third base through electrode T73 and outputs the data DATA to the memory controller 72.

The third base pad BP73 is electrically connected to one of a seventh bump 717, an eighth bump 718, and a ninth bump 719 depending on a location of the third base pad BP73 relative to a corresponding core pad. When the third base pad BP73 is disposed at a corresponding location to a seventh core pad CP87, the third base pad BP73 is electrically connected to the seventh bump 717. When the third base pad BP73 is disposed at a corresponding location to an eighth core pad CP88, the third base pad BP73 is electrically connected to the eighth bump 718. When the third base pad BP73 is disposed at a corresponding location to a ninth core pad CP89, the third base pad BP73 is electrically connected to the ninth bump 719.

The first base pad BP71, the second base pad BP72, and the third base pad BP73 may be disposed spaced apart from each other by the same distance. The first base through electrode T71, the second base through electrode T72, and the third base through electrode T73 may be disposed spaced apart from each other by the same distance. The first base pad BP71, the second base pad BP72, and the third base pad BP73 are disposed between a surface of the based chip 70 and the interface circuit 71 and the memory controller 72, which surface may be a top surface or a bottom surface of the base chip 70 relative to the orientation of FIG. 5.

The first core chip 80 is vertically stacked on or over the base chip 70 utilizing the bumps 711 to 719.

The first core chip 80 includes a first path 81, a second path 82, a third path 83, a first channel region CH 84, and a second channel region CH 85.

The first path 81 includes a first core through electrode T81, a second core through electrode T82, a third core through electrode T83, the first core pad CP81, the second core pad CP82, and the third core pad CP83.

The first core pad CP81, the second core pad CP82, and the third core pad CP83 that are included in the first path 81 may be implemented with redistribution layers RDLs and electrically connected.

The structure in which the first bump 711, the second bump 712, the third bump 713, the first core through electrode T81, the second core through electrode T82, the third core through electrode T83, the first core pad CP81, the second core pad CP82, and the third core pad CP83 are electrically connected is similar to the structure in which the first bump 111, the second bump 112, the third bump 113, the first core through electrode T21, the second core through electrode T22, the third core through electrode T23, the first core pad CP21, the second core pad CP22, and the third core pad CP23 illustrated in FIG. 1 are electrically connected.

The second path 82 includes a fourth core through electrode T84, a fifth core through electrode T85, a sixth core through electrode T86, the fourth core pad CP84, the fifth core pad CP85, and the sixth core pad CP86.

The fourth core pad CP84, the fifth core pad CP85, and the sixth core pad CP86 that are included in the second path 82 may be implemented with redistribution layers RDLs and electrically connected.

The structure in which the fourth bump 714, the fifth bump 715, the sixth bump 716, the fourth core through electrode T84, the fifth core through electrode T85, the sixth core through electrode T86, the fourth core pad CP84, the fifth core pad CP85, and the sixth core pad CP86 are electrically connected is similar to the structure in which the fourth bump 114, the fifth bump 115, the sixth bump 116, the fourth core through electrode T24, the fifth core through electrode T25, the sixth core through electrode T26, the fourth core pad CP24, the fifth core pad CP25, and the sixth core pad CP26 illustrated in FIG. 1 are electrically connected.

The third path 83 includes a seventh core through electrode T87, an eighth core through electrode T88, a ninth core through electrode T89, the seventh core pad CP87, the eighth core pad CP88, and the ninth core pad CP89.

The seventh core pad CP87, the eighth core pad CP88, and the ninth core pad CP89 that are included in the third path 83 may be implemented with redistribution layers RDLs and electrically connected.

The structure in which the seventh bump 717, the eighth bump 718, the ninth bump 719, the seventh core through electrode T87, the eighth core through electrode T88, the ninth core through electrode T89, the seventh core pad CP87, the eighth core pad CP88, and the ninth core pad CP89 are electrically connected is similar to the structure in which the seventh bump 117, the eighth bump 118, the ninth bump 119, the seventh core through electrode T27, the eighth core through electrode T28, the ninth core through electrode T29, the seventh core pad CP27, the eighth core pad CP28, and the ninth core pad CP29 illustrated in FIG. 1 are electrically connected.

The first channel region 84 and the second channel region 85 perform similar operations as performed by the first channel region 24 and the second channel region 25, respectively, as illustrated in FIG. 1.

The first path 81, the second path 82, and the third path 83 are disposed in a region along the first direction DIR 1 between a surface of the first core chip 80 and the first channel region 84 and the second channel region 85 of the first core chip 80. The first path 81, the second path 82, and the third path 83 may be disposed near an edge of the surface of the first core chip 80. The surface of the first core chip 80 may be the top surface or the bottom surface of the first core chip 80 relative to the orientation of FIG. 5.

The second core chip 90 is vertically stacked on or over the first core chip 80 utilizing the bumps 811 to 819.

The second core chip 90 includes a fourth path 91, a fifth path 92, a sixth path 93, a third channel region CH 94, and a fourth channel region CH 95.

The fourth path 91 includes a tenth core through electrode T91, an eleventh core through electrode T92, a twelfth core through electrode T93, a tenth core pad CP91, an eleventh core pad CP92, and a twelfth core pad CP93.

The tenth core pad CP91, the eleventh core pad CP92, and the twelfth core pad CP93 that are included in the fourth path 91 may be implemented with redistribution layers RDLs and electrically connected.

The structure in which the tenth bump 811, the eleventh bump 812, the twelfth bump 813, the tenth core through electrode T91, the eleventh core through electrode T92, the twelfth core through electrode T93, the tenth core pad CP91, the eleventh core pad CP92, and the twelfth core pad CP93 are electrically connected is similar to the structure in which the tenth bump 211, the eleventh bump 212, the twelfth bump 213, the tenth core through electrode T31, the eleventh core through electrode T32, the twelfth core through electrode T33, the tenth core pad CP31, the eleventh core pad CP32, and the twelfth core pad CP33 illustrated in FIG. 1 are electrically connected.

The fifth path 92 includes a thirteenth core through electrode T94, a fourteenth core through electrode T95, a fifteenth core through electrode T96, a thirteenth core pad CP94, a fourteenth core pad CP95, and a fifteenth core pad CP96.

The thirteenth core pad CP94, the fourteenth core pad CP95, and the fifteenth core pad CP96 that are included in the fifth path 92 may be implemented with redistribution layers RDLs and electrically connected.

The structure in which the thirteenth bump 814, the fourteenth bump 815, the fifteenth bump 816, the thirteenth core through electrode T94, the fourteenth core through electrode T95, the fifteenth core through electrode T96, the thirteenth core pad CP94, the fourteenth core pad CP95, and the fifteenth core pad CP96 are electrically connected is similar to the structure in which the thirteenth bump 214, the fourteenth bump 215, the fifteenth bump 216, the thirteenth core through electrode T34, the fourteenth core through electrode T35, the fifteenth core through electrode T56, the thirteenth core pad CP34, the fourteenth core pad CP35, and the fifteenth core pad CP36 illustrated in FIG. 1 are electrically connected.

The sixth path 93 includes a sixteenth core through electrode T97, a seventeenth core through electrode T98, an eighteenth core through electrode T99, a sixteenth core pad CP97, a seventeenth core pad CP98, and an eighteenth core pad CP99.

The sixteenth core pad CP97, the seventeenth core pad CP98, and the eighteenth core pad CP99 that are included in the third path 93 may be implemented with redistribution layers RDLs and electrically connected.

The structure in which the sixteenth bump 817, the seventeenth bump 818, the eighteenth bump 819, the sixteenth core through electrode T97, the seventeenth core through electrode T98, the eighteenth core through electrode T99, the sixteenth core pad CP97, the seventeenth core pad CP98, and the eighteenth core pad CP99 are electrically connected is similar to the structure in which the sixteenth bump 217, the seventeenth bump 218, the eighteenth bump 219, the sixteenth core through electrode T37, the seventeenth core through electrode T38, the eighteenth core through electrode T39, the sixteenth core pad CP37, the seventeenth core pad CP38, and the eighteenth core pad CP39 illustrated in FIG. 1 are electrically connected.

The third channel region 94 and the fourth channel region 95 perform similar operations as performed by the third channel region 34 and the fourth channel region 35, respectively, as illustrated in FIG. 1.

The fourth path 91, the fifth path 92 and the sixth path 93 are disposed in a region along the first direction DIR 1 between a surface of the second core chip 90 and the third channel region 94 and the fourth channel region 95 of the second core chip 90. The fourth path 91, the fifth path 92 and the sixth path 93 may be disposed near an edge of the surface of the second core chip 90. The surface of the second core chip 90 may be the top surface or the bottom surface of the second core chip 90 relative to the orientation of FIG. 5.

The structure in which the base pads BP71 to BP73 and the core pads CP81 to CP89 and CP91 to CP99 illustrated in FIG. 5 are electrically connected is similar to the structure in which the base pads BP11 to BP13 and the core pads CP21 to CP29 and CP31 to CP39 illustrated in FIG. 2 or FIG. 3 are electrically connected.

The through electrodes T71 to T73, the core through electrodes T81 to T89, and the core through electrodes T91 to T99 illustrated in FIG. 5 may each be implemented as a cylinder made of conductive material such that the base through electrodes T71 to T73, the core through electrodes T81 to T89, and the core through electrodes T91 to T99 are vertically stacked through the base chip 70, the first core chip 80, and the second core chip 90. The bumps 711 to 819 may each be implemented in the form of a ball made of conductive material such that the bumps 711 to 719 and 811 to 819 may be directly connected to a printed circuit board.

Although the semiconductor device 3 illustrated in FIG. 5 includes the base chip 70, the first core chip 80, and the second core chip 90 in a vertically stacked arrangement, different quantities of core chips, such as 4, 8, and 12, are stacked on or over the base chip 70 according to different embodiments.

As described for the semiconductor device 3 according to an embodiment of the present disclosure, the plurality of pads included in the first and second core chips 80 and 90 is electrically connected, and a pad of the base chip 70 and one of the plurality of pads of the first and second core chips 80 and 90 are connected. Accordingly, pads located at different positions on the base chip 70 and the core chips 80 and 90 can be electrically connected. In the semiconductor device 3, wherever a pad of the base chip 70 is located, the base chip 70 and the core chips 80 and 90 including pads at various different locations can be electrically connected by connecting the pad of the base chip 70 and one of the plurality of pads of the core chips 80 and 90.

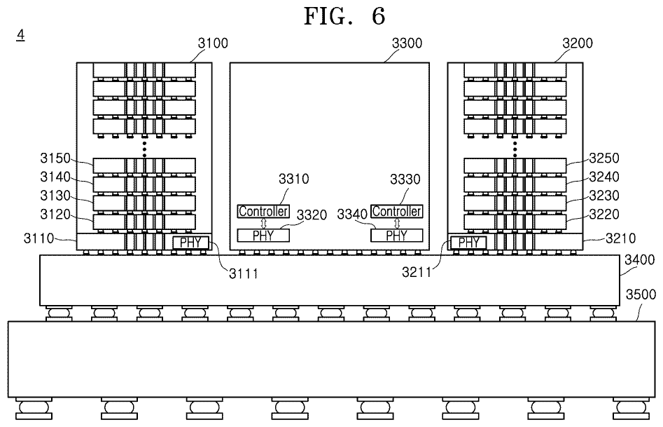

FIG. 6 is a diagram illustrating a stack memory system 4 according to an embodiment of the present disclosure. As illustrated in FIG. 6, the stack memory system 4 includes a first stack memory device 3100, a second stack memory device 3200, a processor 3300, an interposer 3400, and a substrate 3500.

The interposer 3400 is formed on or over the substrate 3500. The first stack memory device 3100, the second stack memory device 3200, and the processor 3300 are formed on or over the interposer 3400. The processor 3300 is formed between the first stack memory device 3100 and the second stack memory device 3200 in this example. The interposer 3400 electrically connects the substrate 3500, the first stack memory device 3100, the second stack memory device 3200, and the processor 3300. Because the pitch difference between the first stack memory device 3100, the second stack memory device 3200, and the processor 3300 may be large, the first stack memory device 3100, the second stack memory device 3200, and the processor 3300 are electrically connected, for example, utilizing conductive lines that are variously formed.

The processor 3300 includes a first controller 3310 that controls the first stack memory device 3100 and a first process interface circuit (PHY) 3320 that electrically connects the first stack memory device 3100 and the first controller 3310. The processor 3300 includes a second controller 3330 that controls the second stack memory device 3200 and a second process interface circuit PHY 3340 that electrically connects the second stack memory device 3200 and the second controller 3330. The processor 3300 conveys signals, including a command and an address that control various internal operations of the first stack memory device 3100, to the first stack memory device 3100 through the first process interface circuit 3320 and receives signals from the first stack memory device 3100 through the first process interface circuit 3320. The processor 3300 conveys signals, including a command and an address that control various internal operations of the second stack memory device 3200, to the second stack memory device 3200 through the second process interface circuit 3340 and receives signals from the second stack memory device 3200 through the second process interface circuit 3340. The first controller 3310 and the second controller 3330 may be implemented with the memory controller 12 illustrated in FIG. 1, the memory controller 42 illustrated in FIG. 4, or the memory controller 72 illustrated in FIG. 5.

The first stack memory device 3100 includes a first base chip 3110 and first core chips 3120, 3130, 3140, and 3150. The first core chips 3120, 3130, 3140, and 3150 are sequentially stacked on or over the first base chip 3110 and receive various signals from the first base chip 3110 via through electrodes. The first stack memory device 3100 is formed to include the four first core chips 3120, 3130, 3140, and 3150, but may be formed by stacking various quantities of core chips, such as 4, 8, 16, or other quantities. The first stack memory device 3100 may be implemented with the semiconductor device 1 illustrated in FIG. 1, the semiconductor device 2 illustrated in FIG. 4, or the semiconductor device 3 illustrated in FIG. 5, including the pad and through electrode arrangements, such as shown in FIG. 1 through FIG. 5.

The first base chip 3110 includes a first core interface circuit PHY 3111. The first core interface circuit 3111 communicates with the first process interface circuit 3320 and receives signals from the processor 3300 and conveys, to the processor 3300, signals generated by the first core chips 3120, 3130, 3140, and 3150. The first core interface circuit 3111 may be implemented with the interface circuit 11 illustrated in FIG. 1, the interface circuit 41 illustrated in FIG. 4, or the interface circuit 71 illustrated in FIG. 5.

The second stack memory device 3200 includes a second base chip 3210 and second core chips 3220, 3230, 3240, and 3250. The second stack memory device 3200 may be implemented with the stack memory device 400 illustrated in FIG. 1. The second core chips 3220, 3230, 3240, and 3250 are sequentially stacked on or over the second base chip 3210 and receive various signals from the second base chip 3210 via through electrodes. The second stack memory device 3200 is formed to include the four second core chips 3220, 3230, 3240, and 3250, but may be formed by stacking various quantities of core chips, such as 4, 8, 16, or other quantities. The second stack memory device 3200 may be implemented with the semiconductor device 1 illustrated in FIG. 1, the semiconductor device 2 illustrated in FIG. 4, or the semiconductor device 3 illustrated in FIG. 5, including the pad and through electrode arrangements, such as shown in FIG. 1 through FIG. 5.

The second base chip 3210 includes a second core interface circuit PHY 3211. The second core interface circuit 3211 communicates with the second process interface circuit 3330 and receives signals from the processor 3300 and conveys, to the processor 3300, signals generated by the second core chips 3220, 3230, 3240, and 3250.

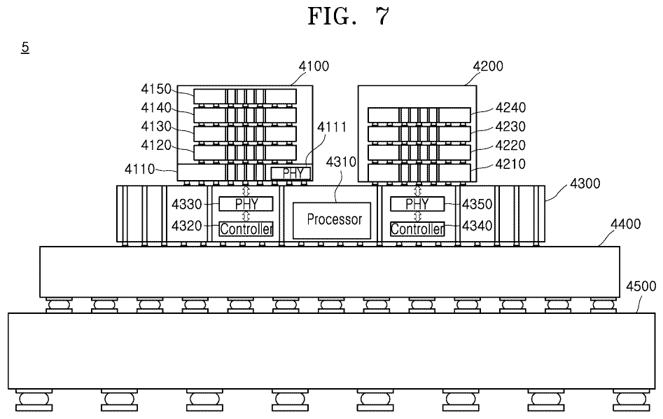

FIG. 7 is a diagram illustrating a stack memory system 5 according to an embodiment of the present disclosure. As illustrated in FIG. 7, the stack memory system 5 includes a first stack memory device 4100, a second stack memory device 4200, a system control device 4300, a substrate 4400, and a main board 4500.

The substrate 4400 is formed on or over the main board 4500. The system control device 4300 is formed on or over the substrate 4400. The first stack memory device 4100 and the second stack memory device 4200 are formed on or over the system control device 4300. The system control device 4300 includes a processor 4310, a first controller 4320, a first process interface circuit PHY 4330, a second controller 4340, and a second process interface circuit PHY 4350.

The processor 4310 is electrically connected to the first controller 4320 to control various internal operations of the first stack memory device 4100. The processor 4310 conveys signals, including a command and an address that control various internal operations of the first stack memory device 4100, to the first stack memory device 4100 through the first process interface circuit 4330 and receives signals from the first stack memory device 4100 through the first process interface circuit 4330. The processor 4310 is electrically connected to the second controller 4340 to control various internal operations of the second stack memory device 4200. The processor 4310 conveys signals, including a command and an address that control various internal operations of the second stack memory device 4100, to the second stack memory device 4200 through the second process interface circuit 4350 and receives signals from the second stack memory device 4200 through the second process interface circuit 4350. The first controller 4320 and the second controller 4340 may be implemented with the memory controller 12 illustrated in FIG. 1, the memory controller 42 illustrated in FIG. 4, or the memory controller 72 illustrated in FIG. 5. The first process interface circuit 4330 and the second process interface circuit 4350 may be implemented with the interface circuit 11 illustrated in FIG. 1, the interface circuit 41 illustrated in FIG. 4, or the interface circuit 71 illustrated in FIG. 5.

The first stack memory device 4100 includes a first base chip 4110 and first core chips 4120, 4130, 4140, and 4150. The first core chips 4120, 4130, 4140, and 4150 are sequentially stacked on or over the first base chip 4110 and receive various signals from the first base chip 4110 via through electrodes. The first stack memory device 4100 is formed to include the four first core chips 4120, 4130, 4140, and 4150, but may be formed by stacking various quantities of core chips, such as 4, 8, 16, or other quantities. The first stack memory device 4100 may be implemented with the semiconductor device 1 illustrated in FIG. 1, the semiconductor device 2 illustrated in FIG. 4, or the semiconductor device 3 illustrated in FIG. 5, including the pad and through electrode arrangements, such as shown in FIG. 1 through FIG. 5.

The first base chip 4110 includes a first core interface circuit 4111 PHY. The first core interface circuit 4111 communicates with the first process interface circuit 4330 and receives signals from the processor 4310 and conveys, to the processor 4310, signals generated by the first core chips 4120, 4130, 4140, and 4150.

The second stack memory device 4200 includes second core chips 4210, 4220, 4230, and 4240. The second stack memory device 4200 may be implemented with the semiconductor device 1 illustrated in FIG. 1. The second core chips 4210, 4220, 4230, and 4240 are sequentially stacked and receive various signals via through electrodes. The second stack memory device 4200 is formed to include the four second core chips 4210, 4220, 4230, and 4240, but may be formed by stacking various quantities of core chips, such as 4, 8, 16 or other quantities. The second stack memory device 4200 is formed such that the core chips are stacked on or over the system control device 4300 without a base chip. The second stack memory device 4200 includes the pad and through electrode arrangements, such as shown in FIG. 1 through FIG. 5.

The second stack memory device 4200 communicates with the second process interface circuit 4350 and receives signals from the processor 4310 and conveys, to the processor 4310, signals generated by the second core chips 4210, 4220, 4230, and 4240.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a base chip comprising a first base pad, a second base pad, and a third base pad; and
a core chip comprising a first path comprising a first plurality of core pads, a second path comprising a second plurality of core pads, and a third path comprising a third plurality of core pads;
wherein the first base pad is electrically connected to one of the first plurality of core pads;
wherein the second base pad is electrically connected to one of the second plurality of core pads;
wherein the third base pad is electrically connected to one of the third plurality of core pads; and
wherein the base chip and the core chip are stacked.

2. The semiconductor device of claim 1, wherein:
the first base pad configured to supply a power supply voltage to the core chip;
the second base pad configured to output a command and an address that control an operation of the core chip; and
the third base pad configured to input and output data stored in the core chip.

3. The semiconductor device of claim 1, wherein:
the first plurality of core pads included in the first path is electrically connected and are supplied with a power supply voltage that is supplied to the core chip;
the second plurality of core pads included in the second path is electrically connected and are supplied with a command and an address that control an operation of the core chip; and
the third plurality of core pads included in the third path is electrically connected and inputs and outputs data stored in the core chip.

4. The semiconductor device of claim 1, wherein:
the first base pad is disposed at a location corresponding to a location of one of the first plurality of core pads;
the second base pad is disposed at a location corresponding to a location of one of the second plurality of core pads; and
the third base pad is disposed at a location corresponding to a location of one of the third plurality of core pads.

5. The semiconductor device of claim 1, wherein the base chip comprises:
an interface circuit configured to receive a control signal input from an external device and to output the control signal to a memory controller and configured to receive data from the memory controller and to output the data to the external device;
the memory controller configured to apply, to the first base pad, a power supply voltage that is supplied to the core chip, configured to receive the control signal from the interface circuit, configured to apply, to the second base pad a command and an address that control an operation of the core chip, and configured to apply, to the third base pad, the data stored in the core chip; and
a pad region comprising the first base pad, the second base pad, and the third base pad.

6. The semiconductor device of claim 5, wherein the first base pad, the second base pad, and the third base pad are disposed between the interface circuit and the memory controller.

7. The semiconductor device of claim 5, wherein the first base pad, the second base pad, and the third base pad are disposed with the interface circuit and the memory controller in a first direction.

8. The semiconductor device of claim 5, wherein the first base pad, the second base pad, and the third base pads are disposed between a surface of the base chip and the interface circuit and the memory controller.

9. A semiconductor device comprising:
a base chip comprising a base pad disposed between an interface circuit and a memory controller and configured to receive a power supply voltage;
a first core chip comprising a first path comprising a first plurality of core pads disposed between a first channel region and a second channel region; and
a second core chip comprising a second path comprising a second plurality of core pads disposed between a third channel region and a fourth channel region;
wherein the base pad is electrically connected to one of the first plurality of core pads and electrically connected to one of the second plurality of core pads; and
wherein the base chip, the first core chip, and the second core chip are stacked.

10. The semiconductor device of claim 9, wherein:
the first plurality of core pads included in the first path is electrically connected; and
the second plurality of core pads included in the second path is electrically connected.

11. The semiconductor device of claim 9, wherein:
the first plurality of core pads included in the first path is disposed spaced apart by a first distance; and
the second plurality of core pads included in the second path is disposed spaced apart by a second distance.

12. The semiconductor device of claim 9, wherein:
the first plurality of core pads is electrically connected to the base pad and is configured to supply the power supply voltage to the first channel region and the second channel region; and
the second plurality of core pads is electrically connected to the base pad and is configured to supply the power supply voltage to the third channel region and the fourth channel region.

13. The semiconductor device of claim 9, wherein:
the base pad is disposed at a location corresponding to a location of one of the first plurality of core pads; and
the base pad is disposed at a location corresponding to a location of one of the second plurality of core pads.

14. The semiconductor device of claim 12, wherein:
the first core pad is disposed at a location corresponding to a location of the fourth core pad;
the second core pad is disposed at a location corresponding to a location of the fifth core pad; and
the third core pad is disposed at a location corresponding to a location of the sixth core pad.

15. A semiconductor device comprising:
a base chip comprising a base pad disposed in a first direction with an interface circuit and a memory controller;
a first core chip comprising a first path comprising a first plurality of core pads disposed in the first direction with a first channel region and a second channel region; and
a second core chip comprising a second path comprising a second plurality of core pads disposed in the first direction with a third channel region and a fourth channel region;
wherein the base pad is electrically connected to one of the first plurality of core pads and electrically connected to one of the second plurality of core pads; and
wherein the base chip, the first core chip, and the second core chip are stacked.

16. The semiconductor device of claim 15, wherein:
the first plurality of core pads included in the first path is electrically connected; and
the second plurality of core pads included in the second path is electrically connected.

17. The semiconductor device of claim 15, wherein:
the first plurality of core pads included in the first path is disposed spaced apart by a first distance; and
the second plurality of core pads included in the second path are disposed spaced apart by a second distance.

18. The semiconductor device of claim 15, wherein:
the first plurality of core pads is electrically connected to the base pad and is configured to supply a power supply voltage, a command, and data to the first channel region and the second channel region; and
the second plurality of core pads is electrically connected to the base pad and is configured to supply the power supply voltage, the command, and the data to the third channel region and the fourth channel region.

19. The semiconductor device of claim 15, wherein the first plurality of core pads comprises a first core pad, a second core pad, and a third core pad, and the second plurality of core pads comprises a fourth core pad, a fifth core pad, and a sixth core pad:
the first core pad is disposed at a location corresponding to a location of the fourth core pad;
the second core pad is disposed at a location corresponding to a location of the fifth core pad; and
the third core pad is disposed at a location corresponding to a location of the sixth core pad.

20. A semiconductor device comprising:
a base chip comprising a base pad disposed in a region between a surface of the base chip and an interface circuit and a memory controller of the base chip;
a first core chip comprising a first path comprising a first plurality of core pads disposed in a region between a surface of the first core chip and a first channel region and a second channel region of the first core chip; and
a second core chip comprising a second path comprising a second plurality of core pads disposed in a region between a surface of the of the second core chip and a third channel region and a fourth channel region of the second core chip;
wherein the base pad is electrically connected to one of the first plurality of core pads and is electrically connected to one of the second plurality of core pads; and
wherein the base chip, the first core chip, and the second core chip are stacked.

21. A semiconductor device comprising:
a base chip comprising a base pad at a first location of a plurality of locations; and
a core chip comprising a first path comprising a plurality of core pads;
wherein the first base pad is electrically connected to one of the plurality of core pads at a location corresponding to the first location;
wherein the base chip and the core chip are stacked.
